(19) United States
(12) Patent Application Publication
(10) Pub. No.: US 2026/0018774 A1
(43) Pub. Date: Jan. 15, 2026

(54) INTEGRATION OF DIRECTIONAL COUPLERS WITH POWER COMBINERS

(71) Applicant: Texas Instruments Incorporated, Dallas, TX (US)

(72) Inventors: Arnab Das, Bangalore (IN); Krishnanshu Dandu, Plano, TX (US)

(21) Appl. No.: 18/813,868

(22) Filed: Aug. 23, 2024

(30) Foreign Application Priority Data
Jul. 10, 2024 (IN) 202441052853

(51) Int. Cl. H01P 5/18; H03H 7/00

(52) U.S. Cl. CPC H01P 5/18; H03H 7/00

(57) ABSTRACT

An example device includes a first primary coil, a second primary coil, a combined power output, a first directional coupler output, a second directional coupler output. The example device also includes a secondary coil coupled to the combined power output, configured to magnetically couple to the first primary coil, and configured to magnetically couple to the second primary coil. The example device further includes a tertiary coil configured to magnetically couple to the secondary coil and including a first end coupled to the first directional coupler output, and a second end coupled to the second directional coupler output.

### CROSS-REFERENCE TO RELATED APPLICATION

This patent application claims the benefit of and priority to Indian Provisional Patent Application No. 202441052853, filed Jul. 10, 2024, which application is hereby incorporated herein by reference in its entirety.

### TECHNICAL FIELD

This description relates generally to power combiners and directional couplers and, more particularly, to integration of directional couplers with power combiners.

### BACKGROUND

Radio communication devices and radar sensor devices may include power combiners to achieve target output transmit powers within semiconductor technology constraints. For example, a millimeter wave (mmWave) radar sensor implemented with a given transistor technology may include a power combiner to implement multiple power amplification stages that achieve a target output power exceeding what could be delivered by individual power amplifiers implemented with that transistor technology. Such radio communication devices and radar sensor devices may also include directional couplers to provide the ability to monitor transmit signals output from the device and/or couple the transmit signals to other device components. For example, a mmWave radar sensor may include a directional coupler to provide the ability to monitor the transmitter output to detect signal reflections indicative of a break in the connection between the transmitter output an antenna, which is referred to herein as a ball break.

### SUMMARY

For methods and apparatus to integrate directional couplers and power combiners, an example device includes a first primary coil, a second primary coil, a combined power output, a first directional coupler output, a second directional coupler output. The example device also includes a secondary coil coupled to the combined power output, configured to magnetically couple to the first primary coil, and configured to magnetically couple to the second primary coil. The example device further includes a tertiary coil configured to magnetically couple to the secondary coil and including a first end coupled to the first directional coupler output, and a second end coupled to the second directional coupler output.

For methods and apparatus to integrate directional couplers and power combiners, another example device includes a first metal layer, a second metal layer different from the first metal layer, a primary coil, a secondary coil implemented in the first metal layer and configured to magnetically couple to the primary coil, and a tertiary coil implemented in the second metal layer and coupled to the secondary coil. In the example device, an area of the secondary coil implemented in the first metal layer at least partially overlaps with an area of the tertiary coil implemented in the second metal layer.

For methods and apparatus to integrate directional couplers and power combiners, an example method to implement an integrated circuit includes positioning a first primary coil and a second primary coil in a first metal layer of the integrated circuit. The method also includes positioning a secondary coil in a second metal layer of the integrated circuit such that an end of the secondary coil is coupled to a power output of the integrated circuit, the second metal layer adjacent to the first metal layer. The method further includes positioning a tertiary coil in a third metal layer of the integrated circuit such that a first end of the tertiary coil is coupled to a first directional coupler output of the integrated circuit and a second end of the tertiary coil is coupled to a second directional coupler output of the integrated circuit, the third metal layer adjacent to the second metal layer, the tertiary coil positioned on top of the secondary coil.

### BRIEF DESCRIPTION OF THE DRAWINGS

FIG. 1 is a block diagram of an example environment in which an example integrated combiner coupler circuit operates to provide ball break detection and power monitoring capabilities for an example device, such as a mmWave radar sensor.

FIG. 2 illustrates port notations for a stand-alone directional coupler.

FIG. 3 is a block diagram of an example mmWave power amplifier circuit that can be used to implement the device of FIG. 1 as an example mmWave radar sensor.

FIG. 4 is a circuit diagram of a stand-alone power combiner coupled with a stand-alone directional coupler.

FIG. 5 illustrates an example structural layout of the stand-alone power combiner and the stand-alone directional coupler of FIG. 4 on a die of an integrated circuit.

FIG. 6 is a circuit diagram of the example integrated combiner coupler circuit of FIG. 1 that includes a power combiner integrated with a directional coupler.

FIG. 7 illustrates example metal layers used to implement the example integrated combiner coupler circuit of FIG. 6.

FIG. 8 illustrates an example structural layout of the example integrated combiner coupler circuit of FIGS. 6 and 7 on a die of an integrated circuit.

FIGS. 9-11 illustrate example performance curves associated with the example integrated combiner coupler circuit of FIGS. 6-8.

FIG. 12 illustrates an example process of making the example integrated combiner coupler circuit of FIGS. 6-8.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Power combiners are utilized in devices, such as radio communications transceivers, radar sensors, analog signal chains, etc., to combine outputs from multiple power amplifiers to yield a target output power that exceeds what could be delivered by individual power amplifiers implemented with a given transistor technology. Directional couplers are also utilized in some such devices to enable the transmitter output to be monitored for the purposes of detecting ball breaks (e.g., breaks in the connections between transmitter outputs and antennas), performing power calibration, monitoring (e.g., gain and/or phase mismatch), functional safety, providing a reference (e.g., local oscillator) for signal down-conversion, etc. However, other devices may implement a power combiner and an associated directional coupler as separate circuits that are connected by a metal trace or other connection that has an associated power loss due to signal propagation along the trace or other connection. Also, some other devices may implement at least portions of the power combiner and the directional coupler in a same metal layer or layers of the integrated circuit die such that the areas of the power combiner and the directional coupler additively contribute to the overall circuit footprint. In other words, the combiner and coupler can be implemented side-by-side in a single metal layer of the device.

In contrast, example integrated combiner coupler circuits described herein integrate a power combiner and a directional coupler in a solution that can avoid the separate metal trace or other connection utilized in other designs. Thus, integrated combiner coupler circuits such as those described herein avoid or at least reduce the power loss associated with the trace or other connection used to connect the separate power combiner and directional coupler in other designs. Furthermore, example integrated combiner coupler circuits described herein implement the power combiner circuitry and the directional coupler circuitry on different metal layers of the integrated circuit die such that the areas of the power combiner circuitry and the directional coupler circuitry overlap (e.g., partially or completely), thereby reducing the circuit footprint relative to other designs. For example, in some integrated combiner coupler circuits, the directional coupler circuitry, or at least a portion thereof, is implemented above (e.g., on top of) the power combiner circuitry, or at least a portion thereof, in the integrated circuit die.

A device implementing the techniques of this disclosure may have a more compact layout than other devices. For example, the chip area occupied by the coils in a device of this disclosure may be substantially less than the chip area occupied by coils in another device. In addition, the techniques of this disclosure may result in lower power losses in the device because of more efficient signal routing. Thus, a device of this disclosure may be more energy efficient and generate less heat, as compared to other devices. Of course, these advantages are merely examples, and no advantage is required for any particular embodiment.

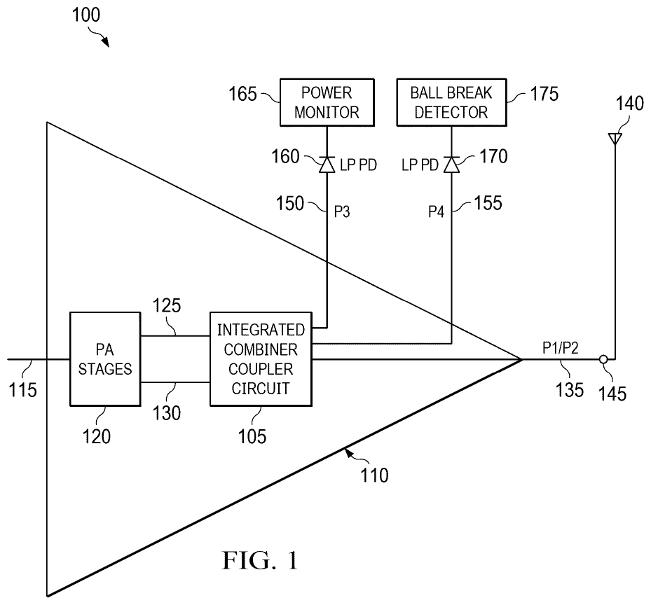

Turning to the figures, an example environment 100 in which an example integrated combiner coupler circuit 105 operates to provide ball break detection and power monitoring capabilities for an example device 110 is illustrated in FIG. 1. For example, the device 110 can be mmWave radar sensor, a radio frequency (RF) communications device/transceiver, any device in an analog signal chain, etc. Device 110 may be implemented as a front-end-only device or as an integrated device that includes front-end and back-end circuitry. In the illustrated example of FIG. 1, the device 110 has an example device input 115 to accept an input signal to be transmitted by the device 110. The device 110 also includes circuitry to process the input signal, including but not limited to one or more example power amplifier stages 120 as illustrated in FIG. 1. The power amplifier stage(s) 120 are provided to amplify the input signal to achieve an output transmit signal having a target transmit power or range of transmit power.

In the illustrated example of FIG. 1, a final stage of the power amplifier stage(s) 120 includes two parallel power amplifiers (not shown) that perform amplification of the input signal in parallel. The outputs of the respective parallel amplifiers of the power amplifier stage(s) 120 are coupled to respective example first and second inputs 125 and 130 of the integrated combiner coupler circuit 105. The integrated combiner coupler circuit 105 combines the amplified signals applied to the first and second inputs 125 and 130 to produce an output transmit signal. As such, the integrated combiner coupler circuit 105 has an example combined power output 135 (labelled P1/P2 in FIG. 1) that provides the output transmit signal from the device 110. In the illustrated example of FIG. 1, the combined power output 135 is coupled to an example antenna 140 via an example solder ball 145 or any other appropriate connection 145.

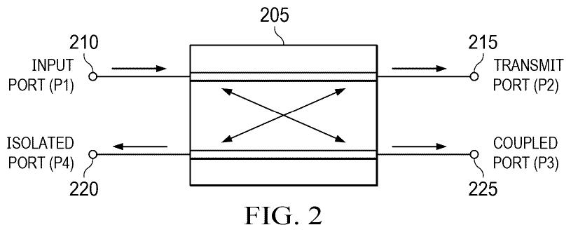

The integrated combiner coupler circuit 105 also provides directional coupler signals via example first and second directional coupler outputs 150 and 155. For reference, port notations for a typical, stand-alone directional coupler 205 are illustrated in FIG. 2. As shown in FIG. 2, the stand-alone directional coupler 205 has an input port 210 (labeled P1 in FIG. 2) and a transmit port 215 (labeled P2 in FIG. 2). The input port 210 accepts an input signal for transmission and passes that signal to the transmit port 215. As such, the stand-alone directional coupler 205 provides a pass-through path between the input port 210 and the transmit port 215.

The stand-alone directional coupler 205 also has directional coupler outputs in the form of a coupled port 220 (labeled P3 in FIG. 2) and an isolated port 225 (labeled P4 in FIG. 2). The coupled port 220 provides a coupled output signal that corresponds to (e.g., is related to, is proportional to, etc.) the incident power of the input signal applied to the input port 210. The isolated port 225 provides an isolated output signal that corresponds to (e.g., is related to, is proportional to, etc.) the reflected power associated with a signal reflected back from the transmit port 215.

Thus, a typical stand-alone directional coupler 205 has a circuit design that couples the input port 210 and the coupled port 220 within some target offset (e.g., such as −7 Decibel-milliwatts (dBm) or some other target loss/offset), and attempts to isolate the input port 210 from the isolated port 220 at a much larger target loss/offset (e.g., such as −30 dBm or more, or some other target loss/offset). Similarly, the circuit design of a typical stand-alone directional coupler 205 couples the transmit port 215 and the isolated port 225 within some target offset (e.g., such as −7 dBm or some other target loss/offset), and attempts to isolate the transmit port 215 from the coupled port 220 at a much larger target loss/offset (e.g., such as −30 dBm or more, or some other target loss/offset).

In the illustrated example of FIG. 1, and with reference to the directional coupler port notations of FIG. 2, the first directional coupler output 150 (labeled P3 in FIG. 1) corresponds to an example coupled port 150 of the integrated combiner coupler circuit 105, and the second directional coupler output 155 (labeled P4 in FIG. 1) corresponds to an example isolated port 155 of the integrated combiner coupler circuit 105. However, unlike the stand-alone directional coupler of FIG. 2, the integrated combiner coupler circuit 105 eliminates the pass-through path between the input port 210 and the transmit port 215 of the typical stand-alone directional coupler in favor of its combined power output 135. As such, the integrated combiner coupler circuit 105 reduces or eliminates the power loss associated with the pass-through path of the typical stand-alone directional.

Also, in the illustrated example, the coupled port 150 of the integrated combiner coupler circuit 105 is coupled to an example low power (LP) power detector (PD) 160 that, in turn, is coupled to an example power monitor 165. The LP PD 160 measures the power at the output of the coupled port 150, which based on the description above, corresponds to (e.g., is related to, is proportional to, etc.) the incident power of the output transmit signal provided by the combined power output 135. As such, the power monitor 165 can utilize the output of the coupled port 150 and the LP PD 160 to monitor the transmit power at the combined power output 135 to facilitate power calibration, etc. Although not shown, in some examples, the output signal from the coupled port 150 can be used as a reference signal related in frequency to the output transmit signal from the combined power output 135. As such, the output signal from the coupled port 150 can form a reference mixing signal to be used by receiver circuitry of the device 110 to perform intermediate frequency or baseband frequency down-conversion of received signals.

Similarly, the isolated port 155 of the integrated combiner coupler circuit 105 of FIG. 1 is coupled to an example LP PD 170 that, in turn, is coupled to an example ball break monitor 175. The LP PD 170 measures the power at the output of the isolated port 155, which based on the description above, corresponds to (e.g., is related to, is proportional to, etc.) the reflected power, if any, reflected back into the combined power output 135. For example, assuming a properly tuned connection between the combined power output 135 and the antenna 140, little to no signal is reflected back into the combined power output 135. However, if the connection is broken, such as due to a ball break associated with the solder ball 145, then the output transmit signal from the combined power output 135 will be reflected back into the combined power output 135. As such, the ball break monitor 175 can utilize the output of the isolated port 155 and the LP PD 170 to monitor the reflected power into the combined power output 135. In some examples, the ball break monitor 175 detects a ball break associated with the solder ball 145 (or any other discontinuity in the connection between the combined power output 135 and the antenna 140) based in comparison of the reflected power measured by the isolated port 155 and the LP PD 170 to one or more thresholds. For example, the ball break monitor 175 may detect the presence of a ball break associated with the solder ball 145 when the reflected power measured by the isolated port 155 and the LP PD 170 satisfies (e.g., meets or exceeds) a threshold.

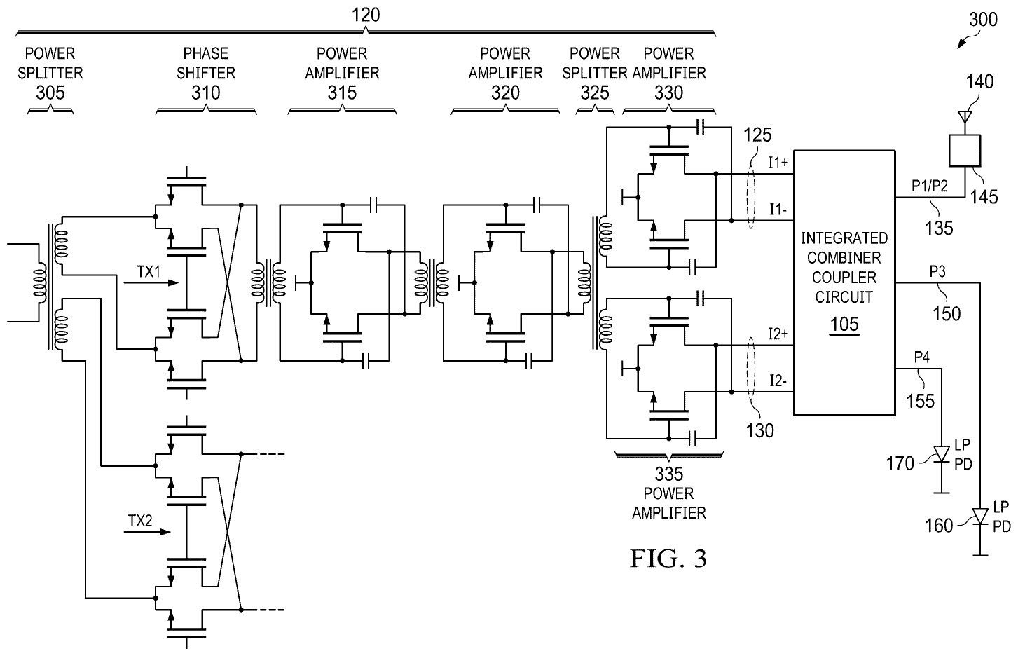

An example mmWave power amplifier circuit 300 that can used to implement the device 110 of FIG. 1 as an example mmWave radar sensor 110 is illustrated in FIG. 3. The mm Wave power amplifier circuit 300 supports an implementation of the mmWave radar sensor 110 that includes a multiple-input and multiple-output (MIMO) transceiver with any number of transmitters (e.g., two transmitters, three transmitters, four transmitters, etc.). For each transmitter, the mmWave power amplifier circuit 300 of the illustrated example implements a power amplifier (PA) chain that includes an example power splitter 305, an example phase shifter 310, example serial power PAs 315 and 320, an example power splitter 325, example parallel PAs 330 and 335, and the integrated combiner coupler circuit 105. With reference to FIG. 1, the power splitter 305, the phase shifter 310, the serial power PAs 315 and 320, the power splitter 325, and the parallel PAs 330 and 335 form the amplifier stages 120.

In the illustrated example mm Wave power amplifier circuit 300 of FIG. 3, the parallel PAs 330 and 335 included in the final stage of the amplifier stages 120 provide differential amplifier outputs. As such, the first input 125 of the integrated combiner coupler circuit 105 of FIG. 3 is a differential input (with inputs labeled I1+ and I1− in FIG. 3), and the second input 130 of the integrated combiner coupler circuit 105 of FIG. 3 likewise is a differential input (with inputs labeled I2+ and I2− in FIG. 3). As in the example of FIG. 1, in the illustrated example of FIG. 3, the combined power output 135 of the integrated combiner coupler circuit 105 is coupled to the antenna 140 via the solder ball 145 or any other appropriate connection 145, and the directional coupler outputs 150 and 155 of the integrated combiner coupler circuit 105 are coupled to their respective LP PDs 160 and 170.

In some examples, such as an example (CMOS) implementation, the mmWave power amplifier circuit 300 can deliver up to 13 dBm output power to the antenna 140 across a bandwidth of 76-81 GHz at a nominal temperature of 140° Celsius (C), which is an improvement of about 0.5 dB over some other layouts that achieve up to 12.5 dBm over the same bandwidth and temperature. In both the mmWave power amplifier circuit 300 and those other layouts, power combining is used to generate approximately 15 dBm power internally, which is then reduced by approximately 2 dB due to package loss. However, other layout exhibit a further loss of approximately 0.5 dB due to the pass-through path of their stand-alone directional couplers.

In the illustrated example of FIG. 3, the directional coupler outputs 150 and 155 provided by the integrated combiner coupler circuit 105 can be used to monitor aspects of the combined power output 135. For example, a power monitor, such as the power monitor 165, can be used with the LP PD 160 to detect the signal power at the coupled port 150 and correlate that power to the power of the output transmit signal from the combined power output 135. Also, a ball break monitor, such as the ball break monitor 175, can be used with the LP PD 170 to detect the signal power at the isolated port 155 and correlate that power to a reflected power at the combined power output 135, which may be indicative of a ball break or other disconnect between the combined power output 135 and the antenna 140. Such ball break monitoring can be important for meeting automotive/industrial safety requirements. In some examples, the directional coupler outputs 150 and 155 provided by the integrated combiner coupler circuit 105 can be used to realize a complex-impedance detection system. In such examples, a reflection coefficient can be measured using incident and reflected wave measurements obtained from the coupled output 150 and the isolated output 155, respectively, and used to detect the presence of a ball break.

As described above, other on-die stand-alone directional coupler implementations exhibit approximately 0.5 dB insertion loss, which is reduced or avoided by the integrated combiner coupler circuit 105 as described in further detail below. Also, in some examples, such as a CMOS implementation, the other on-die implementations that use a stand-alone power combiner and a stand-alone directional coupler implementation can consume a die footprint area of around 0.01 mm². In contrast, the integrated combiner coupler circuit 105 can have a much smaller footprint while achieving an increased 13 dBm output power.

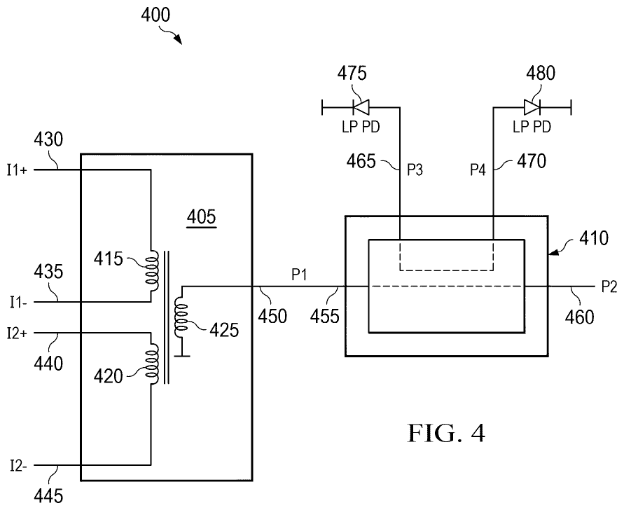

An example circuit diagram 400 for an example stand-alone power combiner 405 coupled with an example stand-alone directional coupler 410 is illustrated in FIG. 4. In the illustrated example of FIG. 4, the stand-alone power combiner 405 corresponds to a distributed active transformer (DAT) based implementation that combines the outputs of two parallel PAS to produce a combined power output. The stand-alone power combiner 405 includes a first primary coil 415, a second primary coil 420 and a secondary coil 425. The ends of the first primary coil 415 are coupled to two inputs 430 and 435 (labeled I1+ and I1− in FIG. 4) that form a first differential input of the stand-alone power combiner 405 to be coupled with a corresponding differential output of a first one of the parallel input PAs (e.g., such as the PA 330 of FIG. 3). The ends of the second primary coil 420 are coupled to two inputs 440 and 445 (labeled I2+ and I2− in FIG. 4) that form a second differential input of the stand-alone power combiner 405 to be coupled with a corresponding differential output of a second one of the parallel input PAs (e.g., such as the PA 335 of FIG. 3).

In the stand-alone power combiner 405 of FIG. 4, the secondary coil 425 is magnetically (e.g., inductively) coupled with the first primary coil 415 and is magnetically (e.g., inductively) coupled with the second primary coil 420. As such, the secondary coil 425 combines the input signal applied to the inputs 430, 435 of the first primary coil 415 and the input signal applied to the inputs 430, 435 of the second primary coil 420 to produce a combined signal. One end of the secondary coil 425 is coupled to an output 450 of the stand-alone power combiner 405, which provides the combined signal to the directional coupler 410.

In the illustrated example of FIG. 4, the directional coupler 410 corresponds to a transformer-style implementation. With reference to the notation illustrated in FIG. 2 and described above, the directional coupler 410 has an input 455 labeled P1 in FIG. 4 to identify the input 455 corresponds to the input port 210 of the reference directional coupler notation. The input 455 of the directional coupler 410 couples to the output 450 of the stand-alone power combiner 405. The directional coupler 410 implements a pass-through path to a transmit output 460 labeled P2 in FIG. 4 to identify the transmit output 460 corresponds to the transmit port 215 of the reference directional coupler notation.

The directional coupler 410 of FIG. 4 also has a first directional coupler output 465 and a second directional coupler output 470 that are magnetically coupled with the pass-through path of the directional coupler 410. The first directional coupler output 465 of the directional coupler 410 is labeled P3 in FIG. 4 to identify the first directional coupler output 465 corresponds to the coupled port 220 of the reference directional coupler notation. The second directional coupler output 470 of the directional coupler 410 is labeled P4 in FIG. 4 to identify the second directional coupler output 470 corresponds to the isolated port 225 of the reference directional coupler notation. In the example of FIG. 4, the first directional coupler output 465 is coupled to a first LP PD 475 that monitors the signal provided at the first directional coupler output 465 (e.g., corresponding to the coupled port 220). Likewise, the second directional coupler output 470 is coupled to a second LP PD 480 that monitors the signal provided at the second directional coupler output 470 (e.g., corresponding to the coupled port 220).

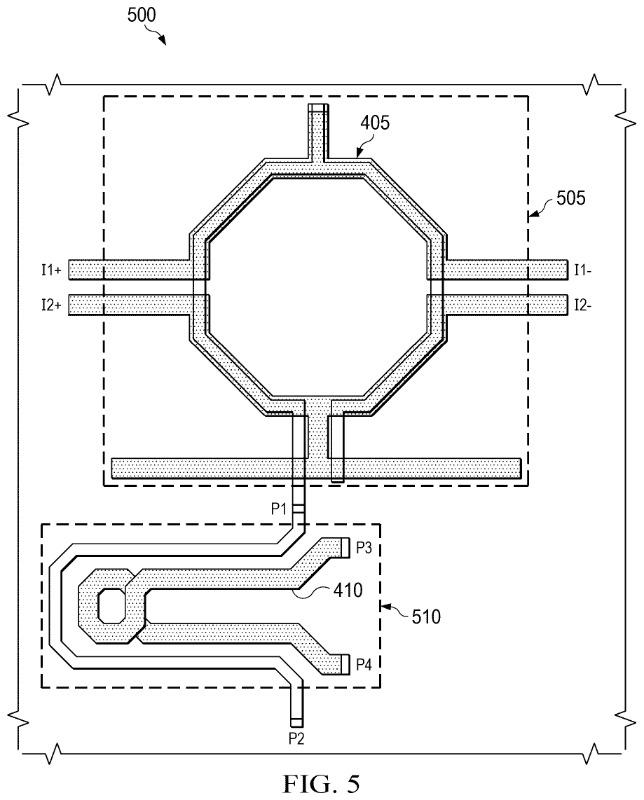

An example structural layout of the stand-alone power combiner 405 and the stand-alone directional coupler 410 of FIG. 4 on an example die 500 of an example integrated circuit is illustrated in FIG. 5. In the illustrated example of FIG. 5, the stand-alone power combiner 405 occupies a first area 505 on the die 500. In the first area 505, the first primary coil 415 and the second primary coil 420 of the stand-alone power combiner 405 are implemented on a first metal layer of the die 500, whereas the secondary coil 425 of the stand-alone power combiner 405 is implemented on a different second layer of the die 500 (e.g., an adjacent layer above, or top of, the first layer).

In the illustrated example of FIG. 5, the stand-alone directional coupler 410 occupies a second area 510 on the die 500. In the second area 510, the stand-alone directional coupler 410 is implemented on the same metal layer as the secondary coil 425 of the stand-alone power combiner 405 (e.g., the second metal layer described above) to facilitate coupling of the output 450 of the stand-alone power combiner 405 with the input 455 of the directional coupler 410. Because the stand-alone directional coupler 410 is implemented on the same metal layer as the secondary coil 425 of the stand-alone power combiner 405, the first area 505 of the stand-alone power combiner 405 and the second area 510 of the stand-alone directional coupler 410 additively contribute to the overall circuit footprint on the die 500, as shown in FIG. 5.

In some examples, the total area of the first area 505 of the stand-alone power combiner 405 and the second area 510 of the stand-alone directional coupler 410 is relatively large, on the order of 0.1 mm² in some examples. Moreover, in an integrated circuit having multiple stand-alone power combiners 405 coupled with corresponding stand-alone directional couplers 410 (e.g., such as the mmWave radar sensor 110 of FIG. 3), the total area occupied by the power combiners and directional couplers scales proportionally, which contributes substantially to the overall circuit footprint on the die 500 and the associated die cost. Also, the length of the pass-through path of the stand-alone directional coupler 410 on the die 500 results in signal loss on the order of 0.5 dB in some examples.

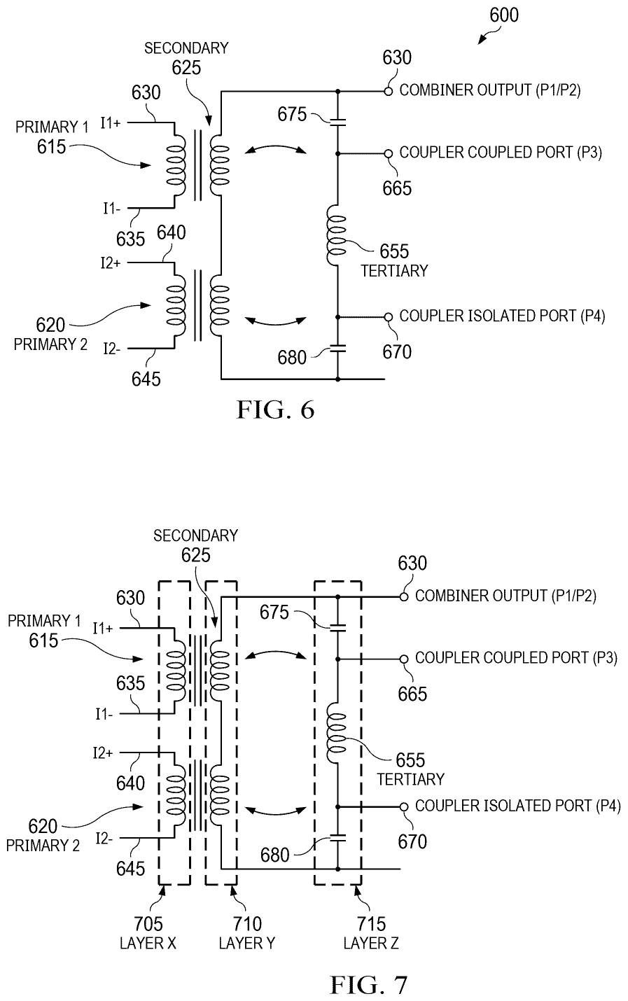

An example circuit diagram 600 of the example integrated combiner coupler circuit 105 of FIG. 1, which includes a power combiner integrated with a directional coupler, is illustrated in FIG. 6. Similar to the circuit 400 of FIG. 4, the integrated combiner coupler circuit 600 of FIG. 6 includes an example first primary coil 615, an example second primary coil 620 and an example secondary coil 625 that implement the power combiner portion of the integrated combiner coupler circuit 600. The ends of the first primary coil 615 are coupled to two example inputs 630 and 635 (labeled I1+ and I1− in FIG. 6) that form a first differential input of the integrated combiner coupler circuit 600 to be coupled with a corresponding differential output of a first one of a set of parallel input PAs (e.g., such as the PA 330 of FIG. 3). The ends of the second primary coil 620 are coupled to two example inputs 640 and 645 (labeled I2+ and I2− in FIG. 6) that form a second differential input of the integrated combiner coupler circuit 600 to be coupled with a corresponding differential output of a second one of the set of parallel input PAs (e.g., such as the PA 335 of FIG. 3).

In the integrated combiner coupler circuit 600 of FIG. 6, the secondary coil 625 is magnetically (e.g., inductively) coupled with the first primary coil 615 and is magnetically (e.g., inductively) coupled with the second primary coil 620. As such, the secondary coil 625 combines the input signal applied to the inputs 630, 635 of the first primary coil 615 and the input signal applied to the inputs 630, 635 of the second primary coil 620 to produce a combined signal. The secondary coil 625 may not be magnetically coupled to the primary coils 615 and 620 while the circuit 600 is powered down, but the secondary coil 625 will be magnetically coupled to the primary coils 615 and 620 during operation of the circuit 600. Similarly, the tertiary coil 625 may not be magnetically coupled to the secondary coils 625 while the circuit 600 is powered down, but the tertiary coil 655 will be magnetically coupled to the secondary coil 625 during operation of the circuit 600. One end of the secondary coil 625 is coupled to an example combiner output 650 of the integrated combiner coupler circuit 600 of FIG. 6, which outputs the combined signal from the integrated combiner coupler circuit 600. The combiner output 650 is also referred to as a combined power output 650. As described in further detail below, the combiner output 650 is labelled P1/P2 in FIG. 6 because the combiner output 650 implements the overall output transmit port of the integrated combiner coupler circuit 600 without use of a pass-through path (or, in other words, the combiner output 650 corresponds to both the input port 210 and the transmit port 215 of the reference directional coupler notation without any intervening pass-through path).

Unlike the circuit 400 of FIG. 4, the integrated combiner coupler circuit 600 of FIG. 6 does not include a separate directional coupler circuit. Rather, the integrated combiner coupler circuit 600 includes an example tertiary coil 655 that is magnetically (e.g., inductively) coupled and electrically (e.g., capacitively) coupled with the secondary coil 625. Through proper design of the magnetic (e.g., inductive) and electrical (e.g., capacitive) coupling between the tertiary coil 655 and the secondary coil 625, the tertiary coil 655 implements the directional coupler portion of the integrated combiner coupler circuit 600. As such, one end of the tertiary coil 655 is coupled to a first directional coupler output 665 of the integrated combiner coupler circuit 600, and the other end of the tertiary coil 655 is coupled to a second directional coupler output 670 of the integrated combiner coupler circuit 600. The first directional coupler output 665 of the integrated combiner coupler circuit 600 is labeled P3 in FIG. 6 to identify the first directional coupler output 665 corresponds to the coupled port 220 of the reference directional coupler notation. The second directional coupler output 670 of the integrated combiner coupler circuit 600 is labeled P4 in FIG. 6 to identify the second directional coupler output 670 corresponds to the isolated port 225 of the reference directional coupler notation.

In the illustrated example of FIG. 6, the electrical (e.g., capacitive) coupling between the tertiary coil 655 and the secondary coil 625 of the integrated combiner coupler circuit 600 is represented by example capacitors 675 and 680 located between the ends of the tertiary coil 655 and the corresponds ends of the secondary coil 625. In some examples, the capacitors 675 and 680 are physical capacitors coupled between the ends of the tertiary coil 655 and the corresponds ends of the secondary coil 625. For example, the first capacitor 675 may be coupled to one end of the tertiary coil 655 and to the end of the secondary coil 625 that is coupled to the combined power output 650, as shown in FIG. 6. The second capacitor 680 may be coupled to the other end of the tertiary coil 655 and to the other end of the secondary coil 625, as also shown in FIG. 6. However, in some examples, the capacitors 675 and 680 are not physical capacitors but corresponds to an inherent capacitance, or an intrinsic capacitance, caused by the tertiary coil 655 and the secondary coil 625 being implemented on different metal layers of the integrated circuit die.

Example metal layers used to implement the example integrated combiner coupler circuit 600 of FIG. 6 is illustrated in FIG. 7. In the illustrated example of FIG. 7, the first primary coil 615 and the second primary coil 620 are implemented in an example first metal layer 705 of an integrated circuit die, the secondary coil 625 is implemented in an example second metal layer 710 of the integrated circuit die, and the tertiary coil 655 is implemented in an example third metal layer 715 of the integrated circuit die. In the illustrated example, the first metal layer 705, the second metal layer 710 and the third metal layer 715 are all different layers of the integrated circuit die. For example, the third metal layer 715 may be adjacent to the second metal layer 710, and the second metal layer 710 may be adjacent to the first metal layer 705, but layers 705, 710, and 715 may not be adjacent in all implementations contemplated by this disclosure. In some examples, the third metal layer 715 is adjacent to and above (or on top of) the second metal layer 710, and the second metal layer 710 is adjacent to and above (or on top of) the first metal layer 705. For example, in an integrated circuit die having nine (9) metal layers, the first metal layer 705 may correspond to the seventh (7^{th}) metal layer (also referred to as MET7), the second metal layer 710 may correspond to the eighth (8^{th}) metal layer (also referred to as MET8), and the third metal layer 715 may correspond to the ninth (9^{th}) metal layer or top metal layer (also referred to as METTOP) of the integrated circuit die. In this example, the third metal layer 715 is the highest metal layer in the integrated circuit die and is immediately on top of the second metal layer 710, and the second metal layer 710 is immediately on top of the first metal layer 705.

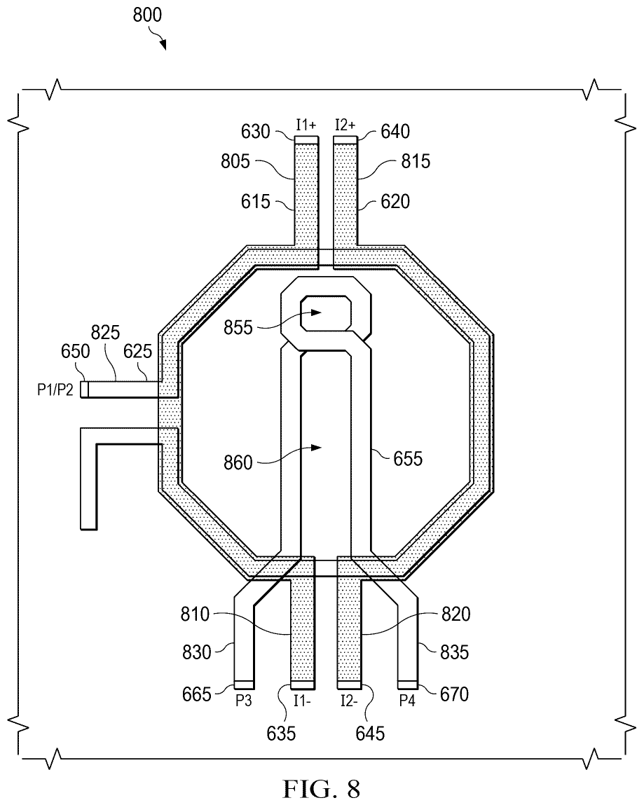

An example structural layout of the example integrated combiner coupler circuit 600 of FIGS. 6 and 7 on an example die 800 of an integrated circuit is illustrated in FIG. 8. In the illustrated example of FIG. 8, a first end 805 and a second end 810 of the first primary coil 615 are coupled respectively to the inputs 630 and 635 (also labeled I1+ and I1−) that form the first differential input of the integrated combiner coupler circuit 600. Similarly, a first end 815 and a second end 820 of the secondary primary coil 620 are coupled respectively to the inputs 640 and 645 (also labeled I1+ and I1−) that form the second differential input of the integrated combiner coupler circuit 600. In the illustrated example of FIG. 8, an end 825 of the secondary coil 625 is coupled to the combined power output 650 (also labelled P1/P2) of the integrated combiner coupler circuit 600. In the illustrated example of FIG. 8, a first end 830 of the tertiary coil 655 is coupled to the first directional coupler output 665 (also labeled P3) of the integrated combiner coupler circuit 600, and a second end 835 of the tertiary coil 655 is coupled to the second directional coupler output 670 (also labeled P4) of the integrated combiner coupler circuit 600.

In the illustrated example of FIG. 8, the first primary coil 615 and the second primary coil 620 are implemented in a first metal layer of the integrated circuit die 800 (e.g., such as the first metal layer 705 described above). In the illustrated example of FIG. 8, the secondary coil 625 is implemented in a second metal layer of the integrated circuit die 800 that is different from the first metal layer (e.g., such as the second metal layer 710 described above.) In the illustrated example of FIG. 8, the tertiary coil 655 is implemented in a third metal layer of the integrated circuit die (e.g., such as the third metal layer 715 described above).

Because the primary coils 615 and 620, the secondary coil 625 and the tertiary coil 655 are implemented in different metal layers, the primary coils 615 and 620, the secondary coil 625 and the tertiary coil 655 can be positioned on the die 800 such that their respective areas spatially overlap (e.g., at least partially or completely). For example, as shown in FIG. 8, the secondary coil 625 is positioned on the second layer of the die 800 and the primary coils 615 and 620 are positioned on the first layer of the die 800 such that the area of the secondary coil 625 (or at least a portion thereof) overlaps with (e.g., is above or on top of) the area of the primary coils 615 and 620 (or at least a portion thereof). Similarly, the tertiary coil 655 is positioned on the third layer of the die 800 such that the area of the tertiary coil 655 (or at least a portion thereof) overlaps with (e.g., is above or on top of) the area of the secondary coil 625 (or at least a portion thereof).

FIG. 8 depicts an example layout where the coils 615, 620, 625, and 655 occupy an overlapping die area from a top-down or bottom-up perspective of the die 800. In some examples, a first area or neighborhood on the die 800 occupied by the primary coils 615 and 620 at least partially overlaps with a second area or neighborhood on the die 800 occupied by the secondary coil 625 and/or with a third area or neighborhood on the die 800 occupied by the tertiary coil 655. Similarly in some examples, the second area or neighborhood on the die 800 occupied by the secondary coil 625 at least partially overlaps with the third area or neighborhood on the die 800 occupied by the tertiary coil 655.

As further explanation, the area or neighborhood occupied by a coil can be represented by an imaginary rectangle or another shape drawn around the conductive elements of that coil. The area or neighborhood of one of the coils shown in FIG. 8 may overlap with the area or neighborhood of another coil shown in FIG. 8 by at least 10%, at least 20%, at least 30%, or at least 50%, in some examples. This is in contrast to other devices where there is no overlap among the coils because the coils are implemented on the same metal layer.

Due to the overlapping areas of the primary coils 615 and 620, the secondary coil 625 and the tertiary coil 655 in the die 800, the integrated combiner coupler circuit 600 has a total area on the die 800 that is less (e.g., substantially less) than the total area of the stand-alone power combiner 405 and stand-alone directional coupler 410 implementation illustrated in FIG. 5. In some examples, the integrated combiner coupler circuit 600 can achieve a 65% area saving relative to the stand-alone approach of FIG. 5, which can correspond to an area savings of 0.15 mm² area in a transceiver with four transmitters. In some examples, such a substantial area savings per channel enables the integration of more transmitter channels (e.g., 8 transmitters or 16 transmitters) on the die 800, which can be useful for imaging radar applications.

Also, because the tertiary coil 655 overlaps the secondary coil 625 on the die 800, the tertiary coil 655 can be designed to magnetically (e.g., inductively) and electrically (e.g., capacitively) couple with the secondary coil 625 without the use of the pass-through path of the stand-alone approach of FIG. 5, which reduces or eliminates the ohmic loss associated with the pass-through path of the stand-alone directional coupler 410. As a result, the loading on the combined power output 650 of the integrated combiner coupler circuit 600 is reduced relative to the loading on the transmit output 460 of the stand-alone implementation of FIG. 5. This can result in 0.3-0.5 dB higher output power from the integrated combiner coupler circuit 600, which corresponds approximately to a 1-1.5% increase in PA power efficiency which is substantial as mmWave PA efficiency can be approximately 6-8%.

In the illustrated example of FIG. 8, the tertiary coil 655 of the integrated combiner coupler circuit 600 is structured with an example anti-turn that defines an example anti-turn area 855 and an example remaining area 860 of the tertiary coil 655. The remaining area corresponds to the difference between the total area of the tertiary coil 655 and the anti-turn area 855 of the tertiary coil 655. The anti-turn area 855 results in magnetic flux cancellation between the tertiary coil 655 and the secondary coil 625, with the ratio of the size of the anti-turn area 855 to the size of the remaining area 860 corresponding to (e.g., proportional to) the magnetic coupling factor between the tertiary coil 655 and the secondary coil 625. Also, the total area of the tertiary coil 655 (e.g., the sum of the anti-turn area 855 and the remaining area 860) corresponds to (e.g., is proportional to) the capacitance between the tertiary coil 655 and the secondary coil 625. As such, the tertiary coil 655 can be designed to have an anti-turn area 855 and a total area (e.g., the sum of the anti-turn area 855 and the remaining area 860) that yields a target magnetic coupling factor, K, and a target capacitance, C, between the tertiary coil 655 and the secondary coil 625.

In the illustrated example, the target magnetic coupling factor, K, and the target capacitance, C, are determined based on target power offsets to be achieved between the combined power output 650 and the directional coupler outputs 665 and 670 of the integrated combiner coupler circuit 600. For example, and with reference to the description of FIG. 2 above, the target magnetic coupling factor, K, and the target capacitance, C, can be determined to (i) yield a target power offset of −7 dBm (or some other value) between the combined power output 650 and the first directional coupler outputs 665 (e.g., the coupled port) and a target power offset of at least −30 dBm (or some other value) between the combined power output 650 and the second directional coupler output 670 (e.g., the isolated port) for signals output from the combined power output 650, and (ii) yield a target power offset of −7 dBm (or some other value) between the combined power output 650 and the second directional coupler output 670 (e.g., the isolated port) and a target power offset of at least −30 dBm (or some other value) between the combined power output 650 and the first directional coupler outputs 665 (e.g., the coupled port) for signals input to the combined power output 650 (e.g., corresponding to a signal reflection).

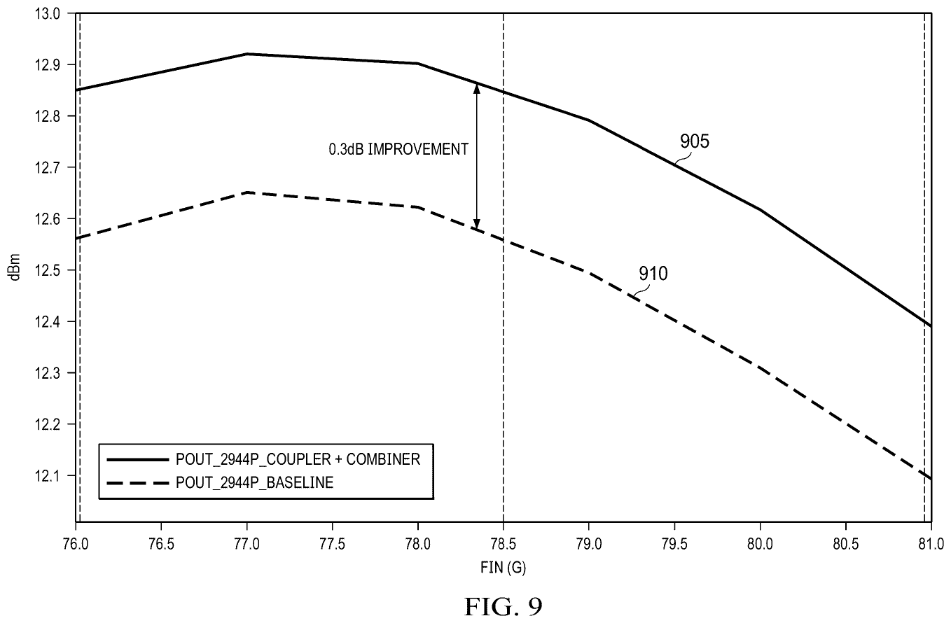

FIGS. 9-11 illustrate example performance curves associated with the example integrated combiner coupler circuit of FIGS. 6-8. FIG. 9 illustrates the improvement in output power achieved by the integrated combiner coupler circuit 600 of FIGS. 6-8 relative to the stand-alone implementation of FIGS. 4-5. In particular, FIG. 9 illustrates a first power graph 905 of output power relative to frequency for the integrated combiner coupler circuit 600. FIG. 9 illustrates a second power graph 910 of output power relative to frequency for the stand-alone implementation of FIGS. 4-5. The power graphs 905 and 910 show that the integrated combiner coupler circuit 600 is able to achieve a 0.3 dB power improvement relative to the stand-alone implementation in the illustrated example.

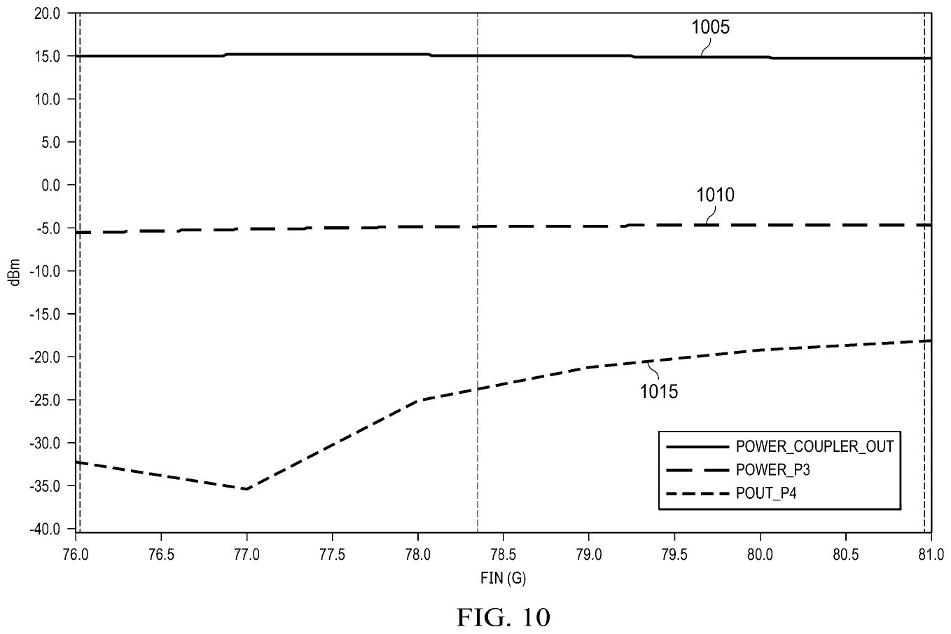

FIG. 10 illustrates the forward wave coupler directivity achieved by the integrated combiner coupler circuit 600. The forward wave coupler directivity corresponds to the power offsets between the combined power output 650 and the directional coupler outputs 665 and 670 of the integrated combiner coupler circuit 600 for signals output from the integrated combiner coupler circuit 600 (e.g., forward waves). FIG. 10 illustrates a first power graph 1005 of output power relative to frequency at the combined power output 650 of the integrated combiner coupler circuit 600 for a forward wave. FIG. 10 also illustrates a second power graph 1010 and a third power graph 1015 of output power relative to frequency at the first directional coupler output 665 and at the second directional coupler output 670, respectively, of the integrated combiner coupler circuit 600 for a forward wave. The power graphs 1005-1015 show that the first directional coupler output 665 operates as a coupled port of a directional coupler and the second directional coupler output 670 operates as an isolated port of a directional coupler for signals output from the integrated combiner coupler circuit 600.

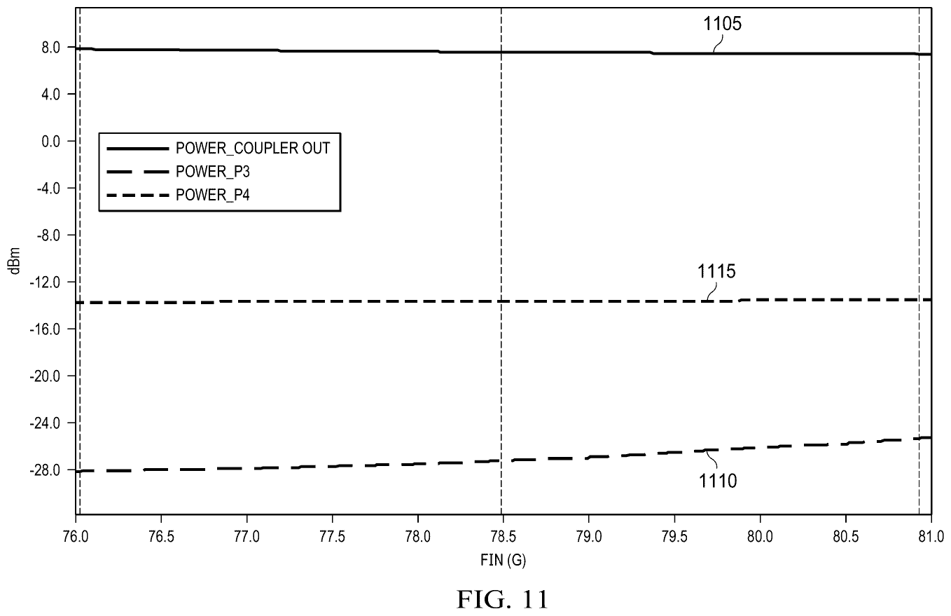

FIG. 11 illustrates the reverse wave coupler directivity achieved by the integrated combiner coupler circuit 600. The reverse wave coupler directivity corresponds to the power offsets between the combined power output 650 and the directional coupler outputs 665 and 670 of the integrated combiner coupler circuit 600 for signals input to the integrated combiner coupler circuit 600 (e.g., reflected, or reverse, waves). FIG. 11 illustrates a first power graph 1105 of output power relative to frequency at the combined power output 650 of the integrated combiner coupler circuit 600 for a reverse (e.g., reflected) wave. FIG. 11 also illustrates a second power graph 1110 and a third power graph 1115 of output power relative to frequency at the first directional coupler output 665 and at the second directional coupler output 670, respectively, of the integrated combiner coupler circuit 600 for a reverse (e.g., reflected) wave. The power graphs 1105-1115 also show that the first directional coupler output 665 operates as a coupled port of a directional coupler and the second directional coupler output 670 operates as an isolated port of a directional coupler for signals input to the integrated combiner coupler circuit 600 (e.g., reflected, or reverse, waves).

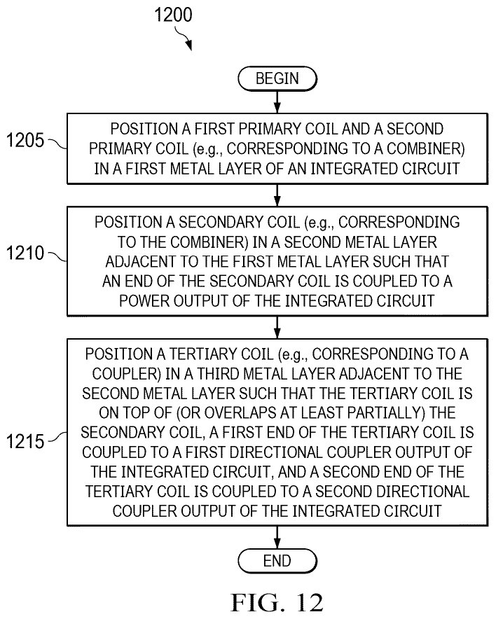

An example process 1200 of making the example integrated combiner coupler circuit 600 of FIGS. 6-8 is illustrated in FIG. 12. The example process 1200 begins at block 1205 at which the first primary coil 615 and the second primary coil 620 of the integrated combiner coupler circuit 600 are positioned (e.g., placed, fabricated, implemented, etc.) on a first metal layer, such as the first metal layer 705, of the integrated circuit die 800, as described above. At block 1210, the secondary coil 625 of the integrated combiner coupler circuit 600 is positioned (e.g., placed, fabricated, implemented, etc.) on a second metal layer, such as the second metal layer 710, of the integrated circuit die 800 such that an end of the secondary coil 625 is coupled to the combined power output 650 of the integrated combiner coupler circuit 600, as described above. For example, at block 1210, the secondary coil 625 is positioned (e.g., placed, fabricated, implemented, etc.) in an adjacent metal layer above (e.g., on top of) the first primary coil 615 and the second primary coil 620 such that the secondary coil 625 overlaps (at least partially) the first primary coil 615 and the second primary coil 620, as described above.

At block 1215, the tertiary coil 655 of the integrated combiner coupler circuit 600 is positioned (e.g., placed, fabricated, implemented, etc.) on a third metal layer, such as the third metal layer 715, of the integrated circuit die 800 such that a first end of the tertiary coil 655 is coupled to the first directional coupler output 665 of the integrated combiner coupler circuit 600 and a second end of the tertiary coil 655 is coupled to the second directional coupler output 670 of the integrated combiner coupler circuit 600, as described above. For example, at block 1215, the tertiary coil 655 is positioned (e.g., placed, fabricated, implemented, etc.) in an adjacent metal layer above (e.g., on top of) the secondary coil 625 such that the tertiary coil 655 overlaps (at least partially) the secondary coil 625, as described above. The example process 1200 then ends.

As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing at least one of a semiconductor device (e.g., a transistor), a semiconductor die containing a semiconductor device, or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. Semiconductor devices are often used in orientation different than their orientation during fabrication. Thus, when referring to one of or a combination of a semiconductor device (e.g., a transistor), a semiconductor die containing a semiconductor device, or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for case of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described to integrate directional couplers and power combiners. Described systems, apparatus, articles of manufacture, and methods improve the efficiency of an integrated circuit or other semiconductor or electrical device by implementing integrated combiner coupler circuits that have reduced area and/or power loss relative to designs based on stand-alone power combiners and stand-alone directional couplers. As such, described systems, apparatus, articles of manufacture, and methods are also directed to one or more improvement(s) in the operation of a machine such as a computer or other electronic, electromechanical, or mechanical device that includes such an integrated combiner coupler circuit.

Further examples and combinations thereof include the following. Example 1 includes a device comprising a first primary coil, a second primary coil, a combined power output, a first directional coupler output, a second directional coupler output, a secondary coil coupled to the combined power output, configured to magnetically couple to the first primary coil, and configured to magnetically couple to the second primary coil, and a tertiary coil configured to magnetically couple to the secondary coil and including a first end coupled to the first directional coupler output, and a second end coupled to the second directional coupler output.
Example 2 includes the device of example 1, wherein the secondary coil is implemented in a first metal layer of the device and the tertiary coil is implemented in a second metal layer of the device, the second metal layer different from the first metal layer.
Example 3 includes the device of example 2, wherein the first metal layer and the second metal layer are adjacent metal layers of the device.
Example 4 includes the device of example 2 or example 3, wherein the second metal layer is a top metal layer of the device.
Example 5 includes the device of any one of examples 2 to 4, wherein an area of the secondary coil and an area of the tertiary coil at least partially overlap.
Example 6 includes the device of example 5, wherein the tertiary coil is on top of the secondary coil.
Example 7 includes the device of example 5 or example 6, wherein the first primary coil and the second primary coil are implemented in a third metal layer of the device, wherein the third metal layer is different from the first metal layer and the second metal layer, and wherein the area of the tertiary coil at least partially overlaps an area of at least one of the first primary coil or the second primary coil.
Example 8 includes the device of example 7, wherein the first metal layer is adjacent to the second metal layer, and the first metal layer is adjacent to the third metal layer.
Example 9 includes the device of any one of examples 1 to 8, wherein the tertiary coil is electrically coupled with the secondary coil based on at least one of (i) an inherent capacitance between the tertiary coil and the secondary coil or (ii) a capacitor that couples the tertiary coil with the secondary coil.
Example 10 includes the device of one of examples 1 to 8, further comprising a first capacitor coupled to the tertiary coil, and a second capacitor coupled to the tertiary coil, wherein the secondary coil includes a first end coupled to the combined power output and to the first capacitor, and a second end coupled to the second capacitor.
Example 11 includes the device of one of examples 1 to 10, wherein the tertiary coil is structured to have an anti-turn to define an anti-turn area of the tertiary coil.
Example 12 includes the device of example 11, wherein the anti-turn is to be positioned to cause a ratio of the anti-turn area to a difference between a total area of the tertiary coil and the anti-turn area to correspond to a target magnetic coupling factor between the tertiary coil and the secondary coil.
Example 13 includes a device comprising a first metal layer, a second metal layer different from the first metal layer, a primary coil, a secondary coil implemented in the first metal layer and configured to magnetically couple to the primary coil, and a tertiary coil implemented in the second metal layer and coupled to the secondary coil, wherein an area of the secondary coil implemented in the first metal layer at least partially overlaps with an area of the tertiary coil implemented in the second metal layer.
Example 14 includes the device of example 13, wherein the first metal layer and the second metal layer are adjacent metal layers.
Example 15 includes the device of example 13 or example 14, wherein the second metal layer is a top metal layer.
Example 16 includes the device of any one of examples 13 to 15, wherein the tertiary coil is on top of the secondary coil.
Example 17 includes the device of any one of examples 13 to 16, further comprising a third metal layer different from the first metal layer and the second metal layer, wherein the primary coil is implemented in the third metal layer, and wherein the area of the tertiary coil at least partially overlaps an area of the primary coil.
Example 18 includes the device of example 17, wherein the first metal layer is adjacent to the second metal layer, and wherein the first metal layer is adjacent to the third metal layer.
Example 19 includes the device of any one of examples 13 to 18, wherein the tertiary coil is coupled to the secondary coil based on at least one of (i) an inherent capacitance between the tertiary coil and the secondary coil or (ii) a capacitor that couples the tertiary coil with the secondary coil.
Example 20 includes a method to implement an integrated circuit, the method comprising positioning a first primary coil and a second primary coil in a first metal layer of the integrated circuit, positioning a secondary coil in a second metal layer of the integrated circuit such that an end of the secondary coil is coupled to a power output of the integrated circuit, the second metal layer adjacent to the first metal layer, and positioning a tertiary coil in a third metal layer of the integrated circuit such that a first end of the tertiary coil is coupled to a first directional coupler output of the integrated circuit and a second end of the tertiary coil is coupled to a second directional coupler output of the integrated circuit, the third metal layer adjacent to the second metal layer, the tertiary coil positioned on top of the secondary coil.

The following claims are hereby incorporated into this Detailed Description by this reference. Although certain example systems, apparatus, articles of manufacture, and methods have been described herein, the scope of coverage of this patent is not limited thereto. On the contrary, this patent covers all systems, apparatus, articles of manufacture, and methods fairly falling within the scope of the claims of this patent.

What is claimed is:

1. A device comprising:
a first primary coil;
a second primary coil;
a combined power output;
a first directional coupler output;
a second directional coupler output;
a secondary coil coupled to the combined power output, configured to magnetically couple to the first primary coil, and configured to magnetically couple to the second primary coil; and
a tertiary coil configured to magnetically couple to the secondary coil and including:
a first end coupled to the first directional coupler output; and
a second end coupled to the second directional coupler output.

2. The device of claim 1,
wherein the secondary coil is implemented in a first metal layer of the device,
wherein the tertiary coil is implemented in a second metal layer of the device, and
wherein the second metal layer is different from the first metal layer.

3. The device of claim 2, wherein the first metal layer and the second metal layer are adjacent metal layers of the device.

4. The device of claim 2, wherein the second metal layer is a top metal layer of the device.

5. The device of claim 2, wherein an area of the secondary coil and an area of the tertiary coil at least partially overlap.

6. The device of claim 5, wherein the tertiary coil is on top of the secondary coil.

7. The device of claim 5,
wherein the first primary coil and the second primary coil are implemented in a third metal layer of the device,
wherein the third metal layer is different from the first metal layer and the second metal layer, and
wherein the area of the tertiary coil at least partially overlaps an area of at least one of the first primary coil or the second primary coil.

8. The device of claim 7,
wherein the first metal layer is adjacent to the second metal layer, and
wherein the first metal layer is adjacent to the third metal layer.

9. The device of claim 1, wherein the tertiary coil is electrically coupled with the secondary coil based on at least one of (i) an inherent capacitance between the tertiary coil and the secondary coil or (ii) a capacitor that couples the tertiary coil with the secondary coil.

10. The device of claim 1, further comprising:
a first capacitor coupled to the tertiary coil; and
a second capacitor coupled to the tertiary coil,
wherein the secondary coil includes:
a first end coupled to the combined power output and to the first capacitor; and
a second end coupled to the second capacitor.

11. The device of claim 1, wherein the tertiary coil is structured to have an anti-turn to define an anti-turn area of the tertiary coil.

12. The device of claim 11, wherein the anti-turn is to be positioned to cause a ratio of the anti-turn area to a difference between a total area of the tertiary coil and the anti-turn area to correspond to a target magnetic coupling factor between the tertiary coil and the secondary coil.

13. A device comprising:
a first metal layer;
a second metal layer different from the first metal layer;
a primary coil;
a secondary coil implemented in the first metal layer and configured to magnetically couple to the primary coil; and
a tertiary coil implemented in the second metal layer and coupled to the secondary coil,
wherein an area of the secondary coil implemented in the first metal layer at least partially overlaps with an area of the tertiary coil implemented in the second metal layer.

14. The device of claim 13, wherein the first metal layer and the second metal layer are adjacent metal layers.

15. The device of claim 13, wherein the second metal layer is a top metal layer.

16. The device of claim 13, wherein the tertiary coil is on top of the secondary coil.

17. The device of claim 13, further comprising a third metal layer different from the first metal layer and the second metal layer,
wherein the primary coil is implemented in the third metal layer, and
wherein the area of the tertiary coil at least partially overlaps an area of the primary coil.

18. The device of claim 17,
wherein the first metal layer is adjacent to the second metal layer, and
wherein the first metal layer is adjacent to the third metal layer.

19. The device of claim 13, wherein the tertiary coil is coupled to the secondary coil based on at least one of (i) an inherent capacitance between the tertiary coil and the secondary coil or (ii) a capacitor that couples the tertiary coil with the secondary coil.

20. A method to implement an integrated circuit, the method comprising:
positioning a first primary coil and a second primary coil in a first metal layer of the integrated circuit;
positioning a secondary coil in a second metal layer of the integrated circuit such that an end of the secondary coil is coupled to a power output of the integrated circuit, the second metal layer adjacent to the first metal layer; and
positioning a tertiary coil in a third metal layer of the integrated circuit such that a first end of the tertiary coil is coupled to a first directional coupler output of the integrated circuit and a second end of the tertiary coil is coupled to a second directional coupler output of the integrated circuit, the third metal layer adjacent to the second metal layer, the tertiary coil positioned on top of the secondary coil.
